(19) United States
(12) Patent Application Publication
(10) Pub. No.: US 2026/0096106 A1
(43) Pub. Date: Apr. 2, 2026

(54) MAGNETIC MEMORY DEVICE AND ELECTRONIC DEVICE COMPRISING THE SAME

(71) Applicant: Samsung Electronics Co., Ltd., Suwon-si (KR)

(72) Inventors: Won Hyeok Heo, Suwon-si (KR); Dae Eun Jeong, Suwon-si (KR); Shin Kwon, Suwon-si (KR)

(21) Appl. No.: 19/291,481

(22) Filed: Aug. 5, 2025

(30) Foreign Application Priority Data
Sep. 27, 2024 (KR) 10-2024-0131469

(51) Int. Cl. H10B 61/00; H10N 50/01; H10N 50/10

(52) U.S. Cl. CPC H10B 61/10; H10N 50/01; H10N 50/10

(57) ABSTRACT

A magnetic memory device includes a substrate including a first region and a second region, an upper insulating layer on the substrate, a first material layer in contact with a first surface of the upper insulating layer, a lower electrode contact in the first material film, a memory structure on the lower electrode contact, a first mold insulating layer on the first material layer and between the first material layer and the memory structure, an etching stop film on the memory structure and the first mold insulating layer, a second mold insulating layer on the upper insulating layer on the second region, and a second material layer in contact with the first surface of the upper insulating layer on the second region and between the upper insulating layer and the second mold insulating layer.

### CROSS-REFERENCE TO RELATED APPLICATIONS

This application claims priority to Korean Patent Application No. 10-2024-0131469 filed in the Korean Intellectual Property Office on September 27, 2024, the contents of which are herein incorporated by reference in its entirety.

### BACKGROUND

Examples of a nonvolatile memory device using a resistance material include a phase change random access memory (PRAM), a resistive RAM (RRAM) and a magnetic memory (MRAM). A Dynamic RAM (DRAM) or a flash memory device stores data by using charges, whereas the nonvolatile memory device using a resistance material stores data by using a state change of a phase change material such as a chalcogenide alloy, a resistance change of a variable resistance material, and a resistance change of a magnetic tunnel junction (MTJ) thin film according to a magnetization state of a ferromagnetic material.

The Magnetic Random Access Memory (MRAM) has received a lot of attention due to its fast read and write speed, high durability, non-volatility, and low power consumption during operation. In addition, MRAM may store information by using a magnetic material as an information-storage medium.

### BRIEF SUMMARY

In general, the present disclosure is directed toward an electronic device having a magnetic memory device with improved reliability.

According to some implementations, the present disclosure is directed to a magnetic memory device that includes a substrate including a first region and a second region, an upper insulating layer on the substrate, a first material layer, which is in contact with a first surface of the upper insulating layer on the first region, on the upper insulating layer, a lower electrode contact in the first material film, a memory structure disposed on the lower electrode contact, including a lower electrode, a magnetic tunnel junction structure and an upper electrode, a first mold insulating layer disposed between the first material layer and the memory structure on the first material layer, an etching stop film on the memory structure and the first mold insulating layer, a second mold insulating layer disposed on the upper insulating layer on the second region, and a second material layer, which is in contact with a first surface of the upper insulating layer on the second region and is different from the first material layer, between the upper insulating layer and the second mold insulating layer.

According to some implementations, the present disclosure is directed to a magnetic memory device that includes a substrate including a first region and a second region, an upper insulating layer on the substrate, a first mold insulating layer disposed on the upper insulating layer on the first region, a lower electrode contact in the first mold insulating layer, a memory structure disposed on the lower electrode contact, including a lower electrode, a magnetic tunnel junction structure and an upper electrode, a second mold insulating layer disposed between the first mold insulating layer and the memory structure on the first mold insulating layer, a third mold insulating layer disposed on the upper insulating layer on the second region, a first etching stop film on the memory structure and the second mold insulating layer in the first region, a second etching stop film disposed between the third mold insulating layer and the upper insulating layer in the second region, a metal structure that is in contact with an upper surface of the memory structure in the first etching stop film, a via contact extended into the second etching stop film, and a first metal wiring disposed on the via contact in the third mold insulating layer, wherein an upper surface of the third mold insulating layer is positioned at the same height as an upper surface of the first etching stop film.

According to some implementations, the present disclosure is directed to a device that includes a logic region, and an electronic device including a memory region connected to the logic region, wherein the memory region is embedded in the electronic device, the memory region includes a cell region and a core peripheral region, the cell region includes a first substrate, a first upper insulating layer on the substrate, a first mold insulating layer disposed on the first upper insulating layer, a diffusion barrier film that is in contact with an upper surface of the first upper insulating layer between the first mold insulating layer and the first upper insulating layer, a lower electrode contact in the first mold insulating layer and the diffusion barrier film, a memory structure disposed on the lower electrode contact, including a lower electrode, a magnetic tunnel junction structure and an upper electrode, a first capping film formed along an upper surface of the first mold insulating layer and a sidewall of the memory structure, a second capping film formed along an upper surface of the first capping film on the first capping film, a second mold insulating layer disposed between the first mold insulating layer and the memory structure on the first mold insulating layer, a first etching stop film disposed on the memory structure and the second mold insulating layer, and a metal structure that is in contact with an upper surface of the memory structure in the first etching stop film, the core peripheral region includes a second substrate, a second upper insulating layer on the second substrate, a third mold insulating layer disposed on the second upper insulating layer, a second etching stop film disposed between the third mold insulating layer and the second upper insulating layer, a via contact extended into the second etching stop film, and a metal wiring disposed on the via contact in the third mold insulating layer, and an upper surface of the third mold insulating layer is positioned at the same height as an upper surface of the first etching stop film.

### BRIEF DESCRIPTION OF THE DRAWINGS

Example implementations will become more clearly understood from the following detailed description, taken in conjunction with the accompanying drawings.

FIG. 1 is a block diagram illustrating an example of an electronic device according to some implementations.

FIG. 2 is a block diagram illustrating an example of a nonvolatile memory of FIG. 1 according to some implementations.

FIG. 3 is a view illustrating an example of a memory cell array according to some implementations.

FIG. 4 is an exemplary view illustrating an example of a memory cell of the memory cell array of FIG. 3 according to some implementations.

FIG. 5 is an exemplary view illustrating an example of a variable resistance element according to some implementations.

FIG. 6 is a top view illustrating an example of an electronic device according to some implementations.

FIG. 7 is a cross-sectional view illustrating an example of an electronic device taken along lines A-A and B-B of FIG. 6 according to some implementations.

FIG. 8 is a cross-sectional view illustrating an example of an electronic device taken along lines C-C and D-D of FIG. 6 according to some implementations.

FIG. 9 is a cross-sectional view of an example of an electronic device according to some implementations.

FIGS. 10 and 11 are cross-sectional views illustrating an example of an electronic device according to some implementations.

FIGS. 12 and 13 are cross-sectional views illustrating an example of an electronic device according to some implementations.

FIGS. 14 to 22 are views illustrating an example of a method of fabricating a semiconductor memory device according to some implementations.

### DETAILED DESCRIPTION

Hereinafter, example implementations will be explained in detail with reference to the accompanying drawings.

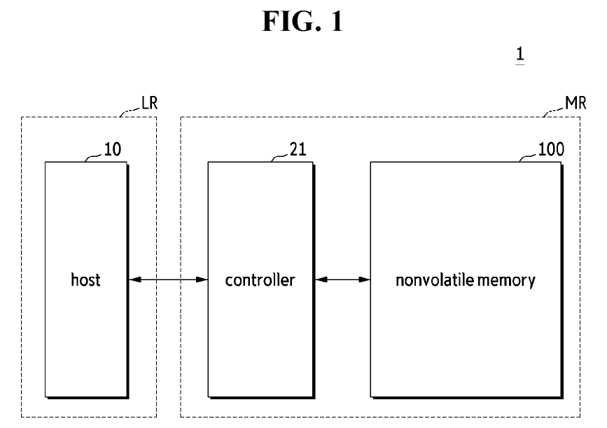

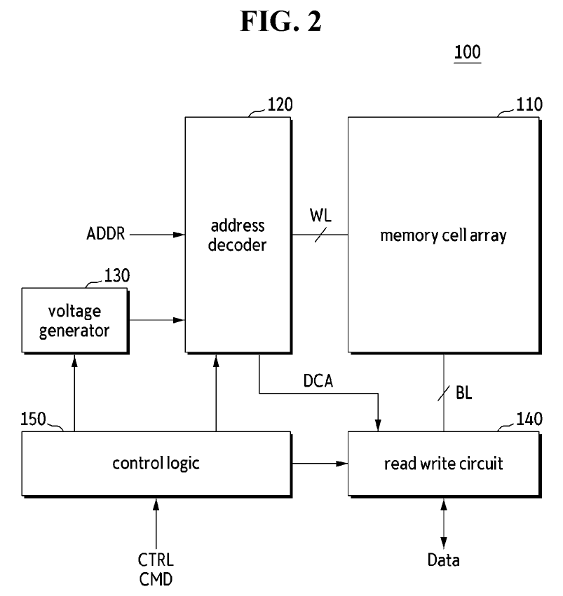

FIG. 1 is a block diagram illustrating an example of an electronic device according to some implementations. FIG. 2 is a block diagram illustrating an example of a nonvolatile memory of FIG. 1 according to some implementations.

In FIG. 1, an electronic device 1 may include a logic region LR and a memory region MR. In this case, the logic region LR may include a host 10, and the memory region MR may include a controller 21 and a nonvolatile memory 100.

In some implementations, the logic region LR may be connected to the memory region MR through an interface. For example, the logic region LR may control the memory region MR by transferring a signal to the memory region MR. Also, for example, the logic region LR may receive the signal from the memory region MR and process data included in the signal.

For example, the host 10 may include a central processing unit (CPU), a controller, or an application specific integrated circuit (ASIC). In addition, for example, the host 10 may include a memory chip, such as a dynamic random access memory (DRAM), a static RAM (SRAM), a phase-change RAM (PRAM), a magneto resistive RAM (MRAM), a ferroelectric RAM (FeRAM), and a Resistive RAM (RRAM).

The memory region MR may include a controller 21 and a nonvolatile memory 100. For example, the nonvolatile memory 100 may include a magnetic random access memory (MRAM), a phase-change RAM (PRAM), a resistive RAM (RRAM), etc., but the present disclosure is not limited thereto. The nonvolatile memory 100 may include various nonvolatile memories, such as an electrically erasable and programmable ROM (EPROM), a flash memory, and a ferroelectric RAM (FRAM), without being limited to the resistive memory.

The controller 21 and the nonvolatile memory 100 may be connected to each other through an interface. The controller 21 may access the nonvolatile memory 100. For example, the controller 21 may control read, write, and erase operations of the nonvolatile memory 100. The controller 21 may function as an interface between the host 10 and the nonvolatile memory 100. The controller 21 may drive firmware for controlling the nonvolatile memory 100.

The interface between host 10 and controller 21 may include various communication standards, such as universal serial bus (USB), multimedia card (MMC), peripheral component interconnection (PCI), PCI-express (PCI-E), Advanced Technology Attachment (ATA), Serial-ATA, Parallel-ATA, small computer small interface (SCSI), enhanced small disk interface (ESDI), integrated drive electronics (IDE), and Firewire.

The memory region MR may include an embedded MRAM embedded in the electronic device 1. In this case, the nonvolatile memory 100 of the memory region MR may be embedded in the electronic device 1. Also, the nonvolatile memory 100 may be embedded in the logic region LR, but the present disclosure is not limited thereto.

In FIG. 2, the nonvolatile memory 100 may include a memory cell array 110, an address decoder 120, a voltage generator 130, a read write circuit 140, and a control logic 150.

The memory cell array 110 may be connected to the address decoder 120 through word lines WL. The memory cell array 110 may be connected to the read write circuit 140 through bit lines BL. The memory cell array 110 may include a plurality of memory cells. For example, memory cells arranged in a row direction may be connected to the word line WL. For example, memory cells arranged in a column direction may be connected to the bit line BL. In this case, the word line WL may include a read word line or a write word line, and the bit line BL may include a bit line or a sensing line.

The address decoder 120 may be connected to the memory cell array 110 through the word line WL. The address decoder 120 may operate in response to the control of the control logic 150. The address decoder 120 may receive an address ADDR from the controller 21. The address decoder 120 may receive a voltage required for a program or read operation from the voltage generator 130.

The address decoder 120 may decode a row address of the received address ADDR. The address decoder 120 may select the word line WL by using the decoded row address. The decoded column address DCA may be provided to the read write circuit 140. For example, the address decoder 120 may include a row decoder, a column decoder, and an address buffer.

The voltage generator 130 may generate a voltage required for an access operation under the control of the control logic 150. For example, the voltage generator 130 may generate a program voltage and a program verification voltage, which are required to perform the program operation. For example, the voltage generator 130 may generate read voltages required to perform the read operation, and may generate an erase voltage and an erase verification voltage, which are required to perform the erase operation. In addition, the voltage generator 130 may provide a voltage required to perform each operation to the address decoder 120.

The read write circuit 140 may be connected to the memory cell array 110 through the bit line BL. The read write circuit 140 may exchange data with the controller 21. The read write circuit 140 may operate in response to the control of the control logic 150. The read write circuit 140 may receive the decoded column address DCA from the address decoder 120. The read write circuit 140 may select the bit line BL by using the decoded column address DCA.

For example, the read write circuit 140 may program the received data into the memory cell array 110. The read write circuit 140 may read data from the memory cell array 110 and provide the read data to an external device (for example, the controller 21). For example, the read write circuit 140 may include elements such as a sense amplifier, a write driver, a column selection circuit and a page buffer.

The control logic 150 may be connected to the address decoder 120, the voltage generator 130, and the read write circuit 140. The control logic 150 may control the operation of the nonvolatile memory 100. The control logic 150 may operate in response to a control signal CRTL and a command CMD (e.g., a write command and a read command), which are provided from the controller 21.

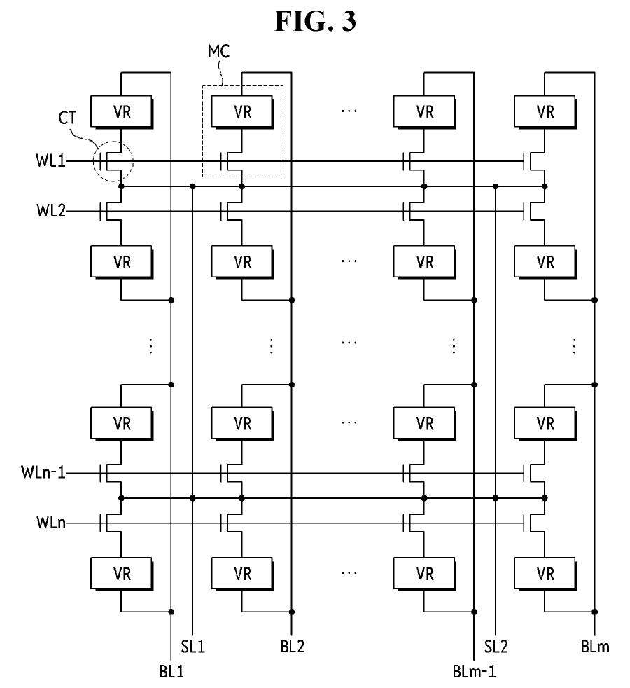

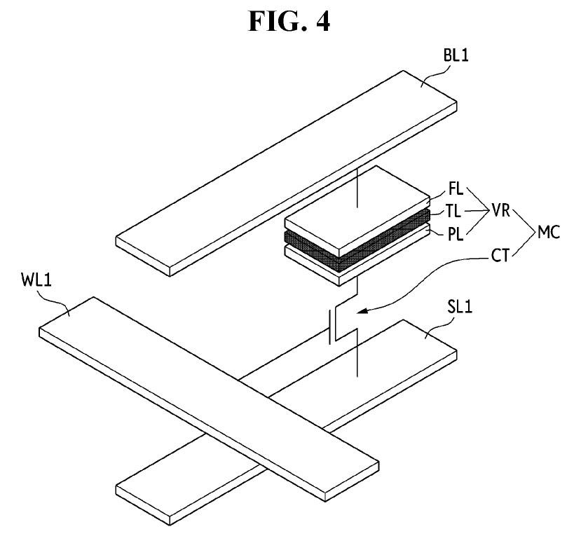

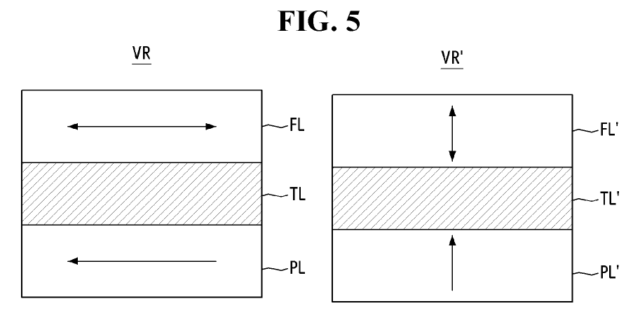

FIG. 3 is a view illustrating an example of a memory cell array according to some implementations. FIG. 4 is an exemplary view illustrating an example of a memory cell of the memory cell array of FIG. 3 according to some implementations. FIG. 5 is an exemplary view illustrating an example of a variable resistance element according to some implementations.

In FIGS. 3 and 4, the memory cell array 110 may include a plurality of memory cells MC. The memory cells MC may be disposed along a row direction and a column direction. The memory cells MC may include, for example, a variable resistance element VR and a cell transistor CT. In this case, the memory region MR including the memory cell array 110 including the memory cells MC may correspond to MRAM.

Gates of the cell transistor CT may be connected to the word lines WL1 to WLn. The gates of the cell transistor CT disposed in the row direction may be connected in common to one word line (e.g., the first word line WL1). The gates of the cell transistor CT in another row may be connected to other word lines.

One end of the cell transistor CT may be connected to one end of the variable resistance element VR. The other end of the cell transistor CT may be connected to a source line (e.g., a source line SL1 and a source line SL2). The other ends of a pair of cell transistors CT adjacent to each other may be connected in common to one source line (e.g., the source line SL1).

One end and the other end of the variable resistance element VR may be connected to the bit lines BL1 to BLm. The other ends of the variable resistance elements VR arranged in the column direction may be connected in common to one bit line (e.g., the first bit line BL1).

The variable resistance element VR may have one of a low resistance state and a high resistance state depending on a bias condition. The state of the variable resistance element VR may be adjusted to one of the low resistance state and the high resistance state, so that data may be stored in the variable resistance element VR.

In FIG. 4, the variable resistance element VR may include a free layer FL, a fixed layer PL, and a tunnel layer TL. For example, the free layer FL, the fixed layer PL and the tunnel layer TL may be disposed between the first bit line BL1 and the cell transistor CT. The tunnel layer TL may be disposed between the free layer FL and the fixed layer PL.

In FIG. 5, a magnetization direction of the fixed layer PL may be fixed. A magnetization direction of the free layer FL may be the same as or opposite to the magnetization direction of the fixed layer PL depending on the bias condition.

When the magnetization direction of the free layer FL and the magnetization direction of the fixed layer PL are parallel (the same direction), a resistance value of the variable resistance element VR may be reduced. When the magnetization direction of the free layer FL and the magnetization direction of the fixed layer PL are anti-parallel, the resistance value of the variable resistance element VR may be increased.

For example, when a current flows from the free layer FL to the fixed layer PL, electrons may move from the fixed layer PL to the free layer FL. The electrons flowing in the fixed layer PL may rotate along the magnetization direction of the fixed layer PL. The free layer FL may be magnetized by electrons rotating in the magnetization direction of the fixed layer PL. For example, the free layer FL may be magnetized in the same direction as the magnetization direction of the fixed layer PL.

For example, when a current flows from the fixed layer PL to the free layer FL, electrons may move from the free layer FL to the fixed layer PL. Some of the electrons injected into the fixed layer PL may be reflected from the fixed layer PL to the free layer FL. The reflected electrons may rotate in the magnetization direction of the fixed layer PL. The rotation direction of the reflected electrons may be opposite to the magnetization direction of the fixed layer PL. The free layer FL may be magnetized by electrons having rotation. That is, the free layer FL may be magnetized in a direction opposite to the magnetization direction of the fixed layer PL.

A variable resistance element VR’ may include a fixed layer PL’, a free layer FL’, and a tunnel layer TL’. Unlike the variable resistance element VR, the fixed layer PL’ and the free layer FL’ of the variable resistance element VR’ may have a magnetization direction in a vertical direction.

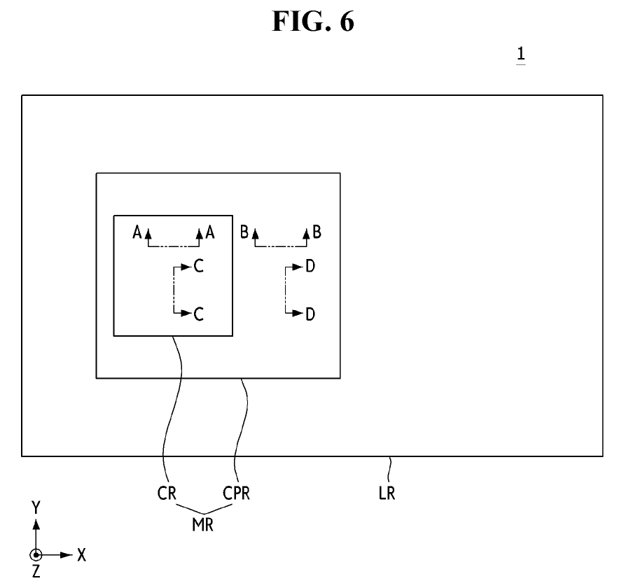

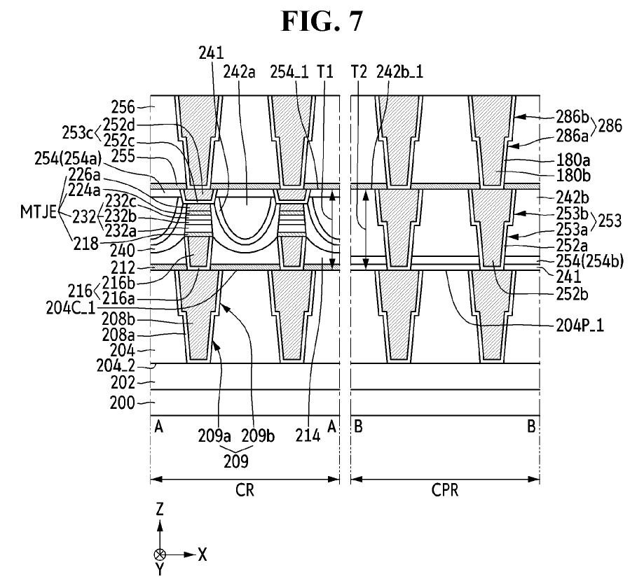

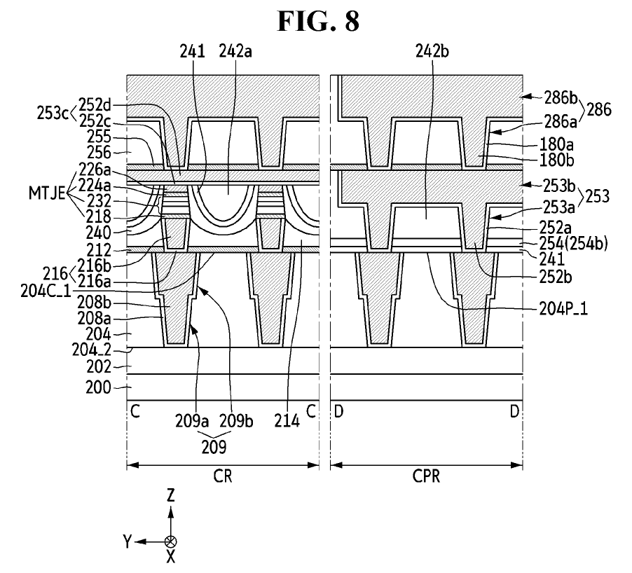

FIG. 6 is a top view illustrating an example of an electronic device according to some implementations. FIG. 7 is a cross-sectional view illustrating an example of an electronic device taken along lines A-A and B-B of FIG. 6 according to some implementations. FIG. 8 is a cross-sectional view illustrating an example of an electronic device taken along lines C-C and D-D of FIG. 6 according to some implementations.

In FIG. 6, the electronic device 1 may include a memory region MR and a logic region LR. As described with reference to FIGS. 1 to 5, the memory region MR may include a controller 21 and a nonvolatile memory 100, and the logic region LR may include a host 10. In this case, the memory region MR may be embedded in the electronic device 1, and in this case, the memory region MR may be an embedded MRAM (eMRAM).

The memory region MR and the logic region LR may be embedded in the electronic device 1. In FIG. 6, the memory region MR may be surrounded by the logic region LR, but the present disclosure is not limited thereto. The memory region MR may include a cell region CR and a core peripheral region CPR. The cell region CR may be surrounded by the core peripheral region CPR, but the embodiments of the present disclosure are not limited thereto.

The cell region CR may correspond to the memory cell array 110 of FIG. 2, and the core peripheral region CPR may correspond to the address decoder 120, the voltage generator 130, the read write circuit 140, and the control logic 150. That is, the cell region CR may include the memory cell array 110 including the memory cell MC, and the core peripheral region CPR may include a peripheral circuit region of the memory cell array 110. In this case, although the cell region CR is shown as being not overlapped by the core peripheral region CPR, the present disclosure is not limited thereto. For example, the core peripheral region CPR may overlap the cell region CR.

In FIGS. 7 and 8, the electronic device 1 may include a substrate 200 and a lower insulating layer 202. For example, the electronic device 1 may include a substrate 200 that includes a cell region CR and a core peripheral region CPR. The substrate 200 may be extended on a plane along a first direction X and a second direction Y. The substrate 200 may include silicon, germanium, silicon-germanium, or a Group III-V compound, such as GaP, GaAs, and GaSb. In some implementations, the substrate 200 may be a silicon-on-insulator (SOI) substrate or a germanium-on-insulator (GOI) substrate.

A circuit pattern formed on the substrate 200 of the cell region CR may include a selection element (e.g., a cell transistor CT) constituting the memory cell MC, and the circuit pattern formed on the substrate 200 of the core peripheral region CPR may include logic transistors corresponding to a logic circuit or a peripheral circuit.

The lower insulating layer 202 may cover the substrate 200. In detail, the lower insulating layer 202 may cover the circuit pattern on the substrate 200. The lower insulating layer 202 may be extended in the first direction X and the second direction Y to cover the substrate 200 corresponding to the cell region CR and the core peripheral region CPR. First lower wirings (not shown) may be formed in the lower insulating layer 202.

The lower insulating layer 202 may include a plurality of interlayer insulating layers. The first lower wirings may be formed in the plurality of interlayer insulating layers. The lower insulating layer 202 may include silicon oxide. The first lower wiring formed in the lower insulating layer 202 may include a contact plug and a conductive pattern. Also, the first lower wiring formed in the lower insulating layer 202 may include polysilicon or metal.

Although thicknesses of the substrate 200 and the lower insulating layer 202 in the third direction Z are shown as being less than those of other layers, the present disclosure is not limited thereto. That is, the substrate 200 and the lower insulating layer 202 may include a plurality of layers, and may have thicknesses greater than those of other layers.

In some implementations, the electronic device 1 may include an upper insulating layer 204, a second lower wiring 209, and the like. The upper insulating layer 204 may be formed on the lower insulating layer 202 in the cell region CR and the core peripheral region CPR.

The upper insulating layer 204 may include first surfaces 204C_1 and 204P_1 and a second surface 204_2, which face each other. The first surfaces 204C_1 and 204P_1 may include a first surface 204C_1 on the cell region CR and a first surface 204P_1 on the core peripheral region CPR. The first surface 204C_1 on the cell region CR may be an upper surface that is in contact with a diffusion barrier film 212 that will be described later. The first surface 204P_1 on the core peripheral region CPR may be an upper surface that is in contact with a second capping film 241 that will be described later. The second surface 204_2 may be a lower surface that is in contact with the lower insulating layer 202.

The second lower wiring 209 may be disposed in the upper insulating layer 204. The second lower wiring 209 may include a contact plug 209a and a lower conductive pattern 209b on the contact plug 209a. An upper surface of the upper insulating layer 204 and an upper surface of the second lower wiring 209 may be positioned on substantially the same plane.

The second lower wiring 209 may include a first barrier pattern 208a and a first conductive pattern 208b. The first barrier pattern 208a may be formed to surround sides and a bottom surface of the first conductive pattern 208b. The first barrier pattern 208a may include, for example, metal nitride, such as tungsten nitride, tantalum nitride, titanium nitride, and/or metal, such as tantalum or titanium. The first conductive pattern 208b may include, for example, copper.

The contact plug 209a may have a cylindrical shape. That is, the contact plug 209a may have a width in the first direction X and the second direction Y. The lower conductive pattern 209b may be formed on the contact plug 209a. The lower conductive pattern 209b may have a cylindrical shape. A width of the lower conductive pattern 209b in the first direction X and the second direction Y may be greater than a width of the contact plug 209a in the first direction X and the second direction Y.

The second lower wiring 209, which includes the contact plug 209a and the lower conductive pattern 209b, may be formed in both the cell region CR and the core peripheral region CPR. That is, the second lower wiring 209 may be formed in the upper insulating layer 204 on both the cell region CR and the core peripheral region CPR, and may be connected to the lower insulating layer 202 and the substrate 200.

The electronic device 1 may include a diffusion barrier film 212, a first mold insulating layer 214, and a lower electrode contact 216. In this case, the diffusion barrier film 212, the first mold insulating layer 214, and the lower electrode contact 216 may be disposed only in the cell region CR, and may not be disposed in the core peripheral region CPR.

The diffusion barrier film 212 may be formed on the upper insulating layer 204 on the cell region CR. The diffusion barrier film 212 may be in contact with the first surface 204C_1 of the upper insulating layer 204 on the cell region CR. Also, the diffusion barrier film 212 may cover the second lower wiring 209 on the cell region CR.

However, in some implementations, the diffusion barrier film 212 may not be disposed on the substrate 200 of the core peripheral region CPR. That is, the diffusion barrier film 212 may not be disposed on the first surface 204P_1 of the upper insulating layer 204 on the core peripheral region CPR. The cell region CR and the core peripheral region CPR may be distinguished from each other by the diffusion barrier film 212.

The diffusion barrier film 212 may include at least one of carbon (C), nitrogen (N), or silicon (Si). The diffusion barrier film 212 may include a silicon (Si)-based material that includes at least one of carbon (C) or nitrogen (N). The diffusion barrier film 212 may include at least one of oxygen (O), nitrogen (N), or aluminum (Al). The diffusion barrier film 212 may include an aluminum (Al)-based material that includes at least one of oxygen (O) or nitrogen (N).

The first mold insulating layer 214 may be formed on the upper insulating layer 204 on the cell region CR. The first mold insulating layer 214 may be formed on the diffusion barrier film 212 on the cell region CR. However, in some implementations, the first mold insulating layer 214 may not be formed on the core peripheral region CPR. The first mold insulating layer 214 may include oxide such as silicon oxide.

The lower electrode contact 216 may be formed in the diffusion barrier film 212 and the first mold insulating layer 214. The lower electrode contact 216 may be formed by passing through the diffusion barrier film 212 and the first mold insulating layer 214. The lower electrode contact 216 may be formed on the cell region CR, but may not be formed on the core peripheral region CPR. The lower electrode contact 216 may be surrounded by the diffusion barrier film 212 and the first mold insulating layer 214.

The lower electrode contact 216 may include a barrier pattern 216a and a conductive pattern 216b. The barrier pattern 216a may include metal nitride, such as tungsten nitride, tantalum nitride and titanium nitride, and/or metal, such as tantalum or titanium, and the conductive pattern 216b may include a conductive material, such as copper.

An upper surface of the first mold insulating layer 214 may have a recessed shape. That is, a thickness of the first mold insulating layer 214 adjacent to the lower electrode contact 216 may be greater than a thickness of the first mold insulating layer 214 far away from the lower electrode contact 216.

In some implementations, the electronic device 1 may include a memory structure MTJE. The memory structure MTJE may be disposed on an upper surface of the lower electrode contact 216. For example, the memory structure MTJE may include a lower electrode 218, a magnetic tunnel junction (MTJ) structure 232, an intermediate electrode film 224a, and an upper electrode 226a. In this case, the lower electrode 218, the MTJ structure 232, the intermediate electrode film 224a, and the upper electrode 226a may be sequentially stacked from the upper surface of the lower electrode contact 216.

In some implementations, the memory structure MTJE may have an inclined sidewall. That is, an area of an upper surface of the memory structure MTJE may be greater than an area of a lower surface of the memory structure MTJE. Also, the area of the lower surface of the memory structure MTJE may be the same as the area of the upper surface of the lower electrode contact 216.

The lower electrode 218 may include metal, such as titanium or tantalum, or metal nitride, such as titanium nitride or tantalum nitride.

The MTJ structure 232 may include a first magnetic pattern 232a, a tunnel barrier pattern 232b, and a second magnetic pattern 232c. The first magnetic pattern 232a may be a fixed layer of which magnetization direction is fixed. For example, the first magnetic pattern 232a may include a fixed pattern, a lower ferromagnetic pattern, an antiferromagnetic coupling spacer pattern, and an upper ferromagnetic pattern. For example, the first magnetic pattern 232a may include manganese iron (FeMn), manganese iridium (IrMn), manganese platinum (PtMn), manganese oxide (MnO), manganese sulfide (MnS), manganese telluride (MnTe), manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), chromium (Cr), and the like. The upper and lower ferromagnetic patterns corresponding to the first magnetic pattern 232a may include, for example, a ferromagnetic material containing at least one of iron (Fe), nickel (Ni), or cobalt (Co). The antiferromagnetic coupling spacer pattern corresponding to the first magnetic pattern 232a may include at least one of, for example, ruthenium (Ru), iridium (Ir), or rhodium (Rh).

The second magnetic pattern 232c may be a free layer having a variable magnetization direction. For example, the second magnetic pattern 232c may include a ferromagnetic material, such as iron (Fe), cobalt (Co), nickel (Ni), chromium (Cr), and platinum (Pt). The second magnetic pattern 232c may further include boron (B) or silicon (Si). Also, the second magnetic pattern 232c may include a composite material, such as CoFe, NiFe, FeCr, CoFeNi, PtCr, CoCrPt, CoFeB, NiFeSiB, and CoFeSiB.

The tunnel barrier pattern 232b may be disposed between the first and second magnetic patterns 232a and 232c. Accordingly, the first and second magnetic patterns 232a and 232c may not be in direct contact with each other. The tunnel barrier pattern 132b may include metal oxide having insulating properties. For example, the tunnel barrier pattern 132b may include magnesium oxide (MgOx) or aluminum oxide (AlOx).

The intermediate electrode 224a may include at least one of metal, such as titanium or tantalum, or metal nitride, such as titanium nitride or tantalum nitride.

The upper electrode 226a may include tungsten, copper, platinum, nickel, silver, gold, etc.

In some implementations, the electronic device 1 may include a first capping film 240, a second capping film 241, a second mold insulating layer 242a, and an etching stop film 254. The first capping film 240 may be formed on the first mold insulating layer 214 on the cell region CR along a sidewall of the memory structure MTJE. That is, the first capping film 240 may be formed to be conformal on surfaces of the first mold insulating layer 214 and the memory structure MTJE on the cell region CR. The first capping film 240 may have a substantially uniform thickness.

The first capping film 240 may be in contact with the sidewall of the memory structure MTJE to protect the memory structure MTJE. The first capping film 240 may include silicon nitride or silicon oxynitride. An upper surface of the first capping film 240 may have a recessed shape like the upper surface of the first mold insulating layer 214.

The second capping film 241 may be disposed between the first capping film 240 and the second mold insulating layer 242a on the first capping film 240. An upper surface of the second capping film 241 may have a recessed shape like the upper surface of the first capping film 240.

The second capping film 241 may include at least one of carbon (C), nitrogen (N), or silicon (Si). The second capping film 241 may include a silicon (Si)-based material containing at least one of carbon (C) or nitrogen (N). The second capping film 241 may include at least one of oxygen (O), nitrogen (N), or aluminum (Al). The second capping film 241 may include an aluminum (Al)-based material containing at least one of oxygen (O) or nitrogen (N).

In some implementations, the diffusion barrier film 212 and the second capping film 241 may include the same material. In some implementations, the diffusion barrier film 212 and the second capping film 241 may include their respective materials different from each other.

The second mold insulating layer 242a may be formed on the first capping film 240 on the cell region CR. The second mold insulating layer 242a may be disposed between the diffusion barrier film 212 and the first mold insulating layer 214 and the memory structure MTJE. The second mold insulating layer 242a may be disposed on the memory structure MTJE, the first capping film 240, and the second capping film 241. The second mold insulating layer 242a may fill a space between the memory structures MTJE. The second mold insulating layer 242a may include oxide, such as silicon oxide.

An upper surface of the second mold insulating layer 242a may be higher than the upper surface of the memory structure MTJE. That is, the second mold insulating layer 242a may completely cover the memory structure MTJE. Meanwhile, the second mold insulating layer 242a may not be formed on the core peripheral region CPR.

The etching stop film 254 may include a first etching stop film 254a on the cell region CR and a second etching stop film 254b on the core peripheral region CPR. The first etching stop film 254a may be disposed on the memory structure MTJE and the first mold insulating layer 242a. The first etching stop film 254a may be formed on the second mold insulating layer 242a. The first etching stop film 254a may include silicon nitride, silicon carbide nitride, etc.

The first etching stop film 254a may be in contact with the second capping film 241 on the cell region CR. The first etching stop film 254a may be in contact with the second mold insulating layer 242a.

In some implementations, the electronic device 1 may include a third metal structure 253c. The third metal structure 253c may be disposed in the second mold insulating layer 242a and the first etching stop film 254a. The third metal structure 253c may include a third barrier pattern 252c and a third conductive pattern 252d.

The third barrier pattern 252c may be formed to be conformal along a trench formed in the second mold insulating layer 242a and the first etching stop film 254a. The third barrier pattern 252c may be in contact with the first etching stop film 254a, the memory structure MTJE, the first capping film 240, and the second capping film 241. Also, the third conductive pattern 252d may fill the trench formed by the third barrier pattern 252c.

In this case, an upper surface of the third metal structure 253 may be in contact with a lower surface of the upper etching stop film 255. Also, a side of the third metal structure 253 may be in contact with the first etching stop film 254a.

In FIG. 8, the third metal structure 253c may be extended to be long in the second direction Y. That is, the third metal structure 253c may have a linear shape, but the embodiments of the present disclosure are not limited thereto.

In FIG. 7, the electronic device 1 may include a third mold insulating layer 242b and a first metal wiring structure 253. The third mold insulating layer 242b may be formed on the diffusion barrier film 212 on the core peripheral region CPR. That is, the third mold insulating layer 242b may not be formed on the cell region CR. The third mold insulating layer 242b may include oxide. For example, the third mold insulating layer 242b may include oxide, such as ultra low-k (ULK). Meanwhile, the second mold insulating layer 242a may include high density plasma-chemical vapor deposition (HDP-CVD) oxide. The second and third mold insulating layers 242a and 242b may include materials different from each other.

The first metal wiring structure 253 may be formed in the second capping film 241, the second etching stop film 254b, and the third mold insulating layer 242b on the core peripheral region CPR. That is, the first metal wiring structure 253 may be formed in a via hole passing through the second capping film 241, the second etching stop film 254b, and the third mold insulating layer 242b.

The first metal wiring structure 253 may include a first via contact 253a and a first metal wiring 253b. The first via contact 253a may be a contact formed in the second capping film 241, the second etching stop film 254b, and the third mold insulating layer 242b. The first metal wiring 253b may be a line formed in the third mold insulating layer 242b.

For example, the first metal wiring 253b may be extended to be long in the second direction Y. Also, a width of the first metal wiring 253b in the first direction X may be greater than a width of the first via contact 253a in the first direction X. An upper surface of the first metal wiring 253b may be exposed to an upper surface of the third mold insulating layer 242b.

The first metal wiring structure 253 may include a second barrier pattern 252a and a second conductive pattern 252b. The second barrier pattern 252a may be formed to be conformal along sides and a bottom surface of the via hole formed in the second capping film 241, the second etching stop film 254b, and the third mold insulating layer 242b. The second conductive pattern 252b may fill a trench formed by the second barrier pattern 252a.

The second capping film 241 may be in contact with the first surface 204P_1 of the upper insulating layer 204 on the core peripheral region CPR. The second capping film 241 may be disposed between the upper insulating layer 204 and the third mold insulating layer 242b. The diffusion barrier 212, which is in contact with the first surface 204C_1 of the upper insulating layer 204 on the cell region CR, and the second capping film 241, which is in contact with the first surface 204P_1 of the upper insulating layer 204 on the core peripheral region CPR, may be different from each other.

The second etching stop film 254b may be disposed between the second capping film 241 and the third mold insulating layer 242b. The second etching stop film 254b may be disposed on the second capping film 241 on the core peripheral region CPR, and may be in contact with the second capping film 241.

A distance T1 from the first surface 204C_1 of the upper insulating layer 204 on the cell region CR to an upper surface 254_1 of the first etching stop film 254a may be the same as a distance T2 from the first surface 204P_1 of the upper insulating layer 204 on the core peripheral region CPR to an upper surface 242b_1 of the third mold insulating layer 242b. In other words, the upper surface 242b_1 of the third mold insulating layer 242b may be positioned at the same height in the third direction Z as the upper surface 254_1 of the first etching stop film 254a.

In FIGS. 7 and 8, the electronic device 1 may include an upper etching stop film 255, a fourth mold insulating layer 256, and a second metal wiring structure 286. The upper etching stop film 255 may be formed in both the cell region CR and the core peripheral region CPR. That is, the upper etching stop film 255 may be formed on the first etching stop film 254a of the cell region CR and the third mold insulating layer 242b on the core peripheral region CPR. A lower surface of the upper etching stop film 255 may be in contact with an upper surface of the first etching stop film 254a. Also, the upper surface of the upper etching stop film 255 may be exposed.

The fourth mold insulating layer 256 may be formed on the upper etching stop film 255. The second metal wiring structure 286 may be formed in the upper etching stop film 255 and the fourth mold insulating layer 256. In the cell region CR, the second metal wiring structure 286 may be connected to the third metal structure 253c, and in the core peripheral region CPR, the second metal wiring structure 286 may be connected to the first metal wiring structure 253.

The second metal wiring structure 286 may include a second via contact 286a and a second metal wiring 286b. The second via contact 286a may be a contact formed in the upper etching stop film 255 and the fourth mold insulating layer 256. The second metal wiring 286b may be a line formed in the fourth mold insulating layer 256. For example, the second metal wiring 286b may be extended to be long in the second direction Y. Also, a width of the second metal wiring 286b in the first direction X may be greater than a width of the second via contact 286a in the first direction X. In this case, the width of the second via contact 286a in the first direction X may be less than a width of the third metal structure 253c in the first direction X.

The second metal wiring structure 286 may include a fourth barrier pattern 180a and a fourth conductive pattern 180b. The fourth barrier pattern 180a may be formed to be conformal along sides and a bottom surface of the via hole formed in the upper etching stop film 255 and the fourth mold insulating layer 256. The fourth conductive pattern 180b may fill a trench formed by the fourth barrier pattern 180a.

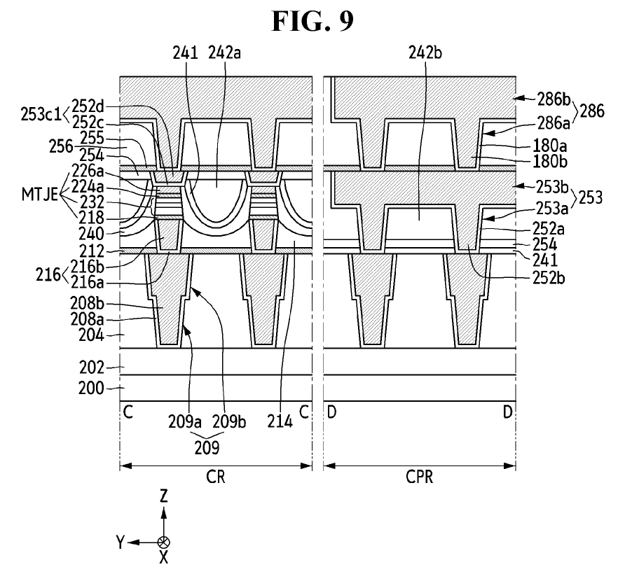

FIG. 9 is a cross-sectional view of an example of an electronic device according to some implementations. For convenience of description, redundant portions of those described above with reference to FIGS. 1 to 8 will be briefly described or omitted.

In FIG. 9, the electronic device 1 may include a via contact 253c1. The electronic device 1 described with reference to FIGS. 1 to 8 includes a third metal structure 253c, whereas the via contact 253c1 may have a via shape. That is, the third structure 253c has a line shape formed to be extended to be long in the second direction Y, whereas the via contact 253c1 may not be extended to be long in the second direction Y. For example, a width of the via contact 253c1 in the first direction X and a width of the via contact 253c1 in the second direction Y may be substantially the same as each other. The via contact 253c1 may directly connect the memory structure MTJE with the second metal wiring structure 286.

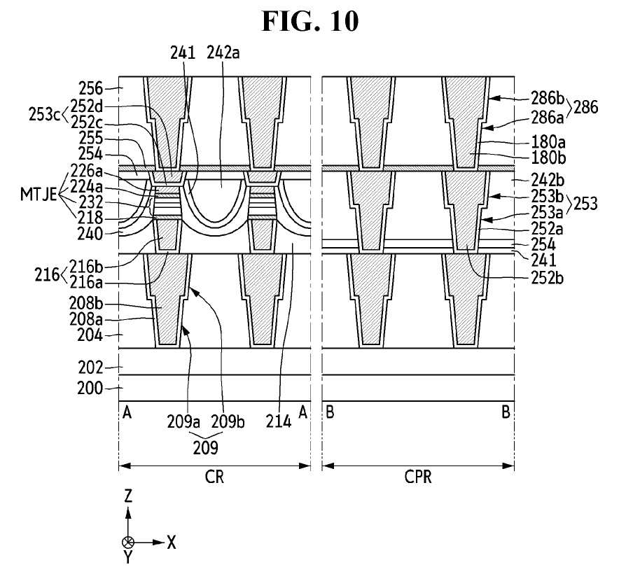

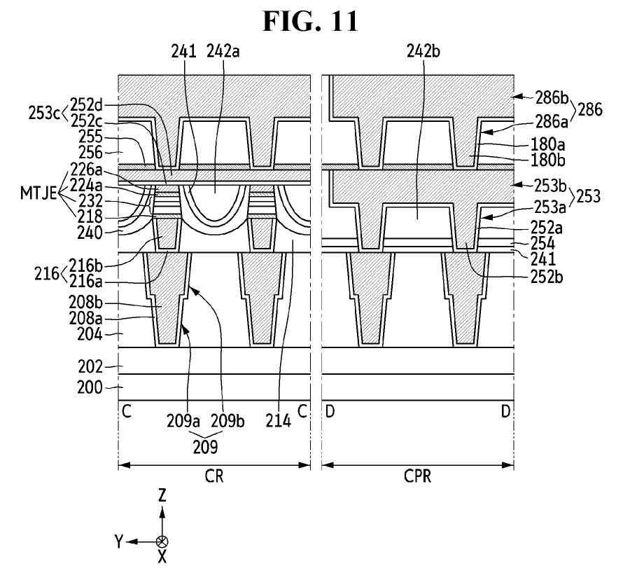

FIGS. 10 and 11 are cross-sectional views illustrating an example of an electronic device according to some implementations. For convenience of description, redundant portions of those described above with reference to FIGS. 1 to 9 will be briefly described or omitted.

In FIGS. 10 and 11, the electronic device 1 may not include the diffusion barrier film 212 unlike the electronic device 1 described with reference to FIGS. 1 to 9. That is, the diffusion barrier film 212 may not be disposed on the first surface 204C_1 of the upper insulating layer 204.

The first mold insulating layer 214 may be disposed on the first surface 204C_1 of the upper insulating layer 204. The first mold insulating layer 214 may be in contact with the first surface 204C_1 of the upper insulating layer 204.

The first mold insulating layer 214, which is in contact with the first surface 204C_1 of the upper insulating layer 204 on the cell region CR, and the second capping film 241, which is in contact with the first surface 204P_1 of the upper insulating layer 204 on the core peripheral region CPR, may be different from each other.

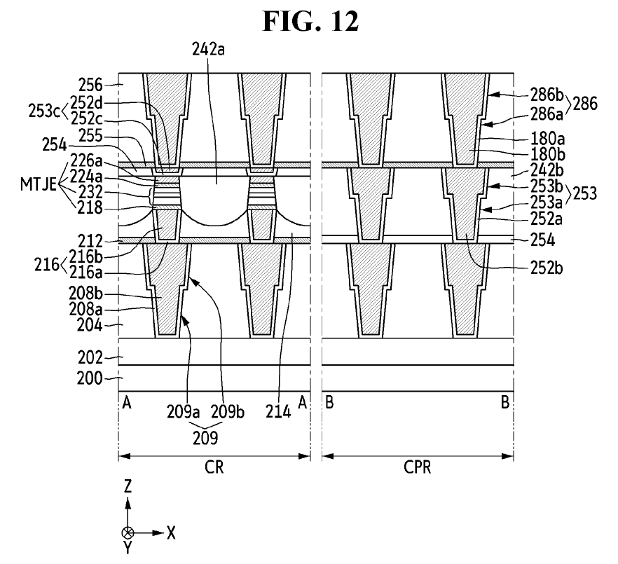

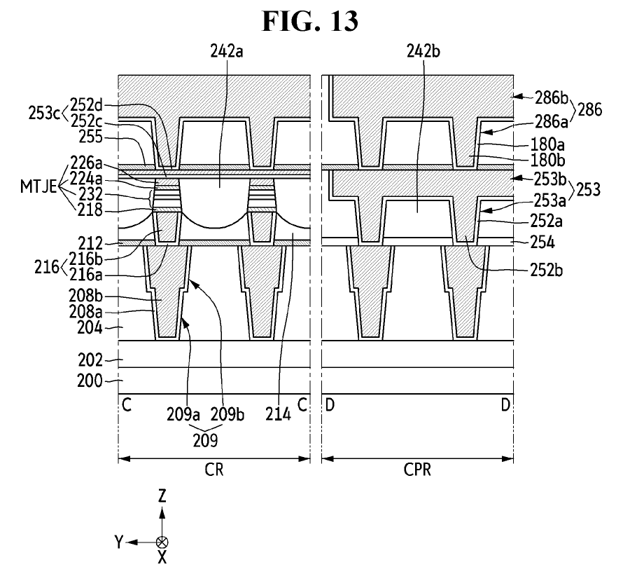

FIGS. 12 and 13 are cross-sectional views illustrating an example of an electronic device according to some implementations. For convenience of description, redundant portions of those described above with reference to FIGS. 1 to 11 will be briefly described or omitted.

In FIGS. 12 and 13, the electronic device 1 may not include the first capping film 240 and the second capping film 241 unlike the electronic device 1 described with reference to FIGS. 1 to 11. The etching stop film 254 on the core peripheral region CPR may be in contact with the first surface 204P_1 of the upper insulating layer 204 on the upper insulating layer 204. The sidewall of the memory structure MTJE may be in contact with the second mold insulating layer 242a. The upper surface of the first mold insulating layer 214 may be in contact with the second mold insulating layer 242a.

The first mold insulating layer 214, which is in contact with the first surface 204C_1 of the upper insulating layer 204 on the cell region CR, and the etching stop film 254, which is in contact with the first surface 204P_1 of the upper insulating layer 204 on the core peripheral region CPR, may be different from each other.

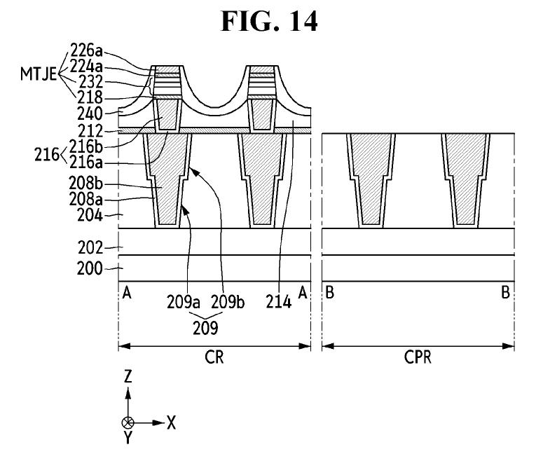

Hereinafter, a method of fabricating the electronic device 1 according to some embodiments will be described with reference to FIGS. 14 to 22.

FIGS. 14 to 22 are views illustrating an example of a method of fabricating a semiconductor memory device according to some implementations. For convenience of description, redundant portions of those described above with reference to FIGS. 1 to 8 will be briefly described or omitted.

In FIG. 14, the diffusion barrier film 212, the lower electrode contact 216, the first mold insulating layer 214, the memory structure MTJE, and the first capping film 240 may be formed on the upper insulating layer 204. Each of the upper surface of the first mold insulating layer 214 and the upper surface of the first capping film 240 on the cell region CR may be formed to be recessed.

The diffusion barrier film 212, the first mold insulating layer 214, and the first capping film 240 on the core peripheral region CPR may be removed so that the upper surface of the upper insulating layer 204 may be exposed. The diffusion barrier film 212, the first mold insulating layer 214, and the first capping film 240 may be removed from the core peripheral region CPR by an ion beam etching process, for example. The diffusion barrier film 212, the first mold insulating layer 214, the first capping film 240, the lower electrode contact 216, and the memory structure MTJE may be selectively formed on the cell region CR.

In some implementations, a film material on the lower wiring 209 of the core peripheral region CPR may be removed. Accordingly, a step difference between film materials on the cell region CR and the core peripheral region CPR, which is formed in a subsequent process, may be minimized.

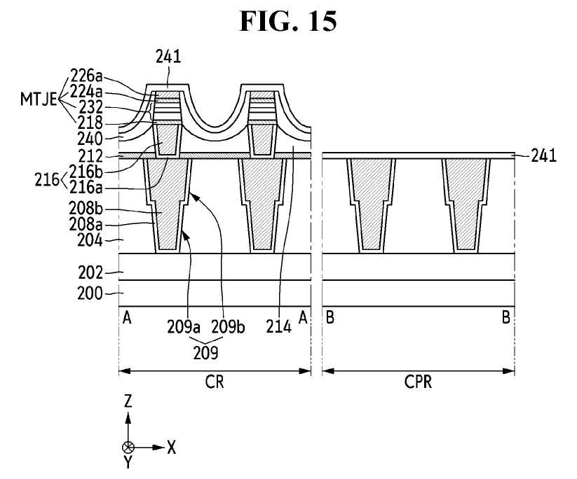

In FIG. 15, the second capping film 241 may be formed on the first capping film 240 and the memory structure MTJE on the cell region CR. Also, the second capping film 241 may be formed on the upper surface of the upper insulating layer 204 of the core peripheral region CPR. In the cell region CR, the second capping film 241 may be formed to be recessed along the upper surface of the first capping film 240. The second capping film 241 may be formed on the upper surface of the memory structure MTJE. In the core peripheral region CPR, the second capping film 241 may be formed to be parallel with the upper surface of the upper insulating layer 204.

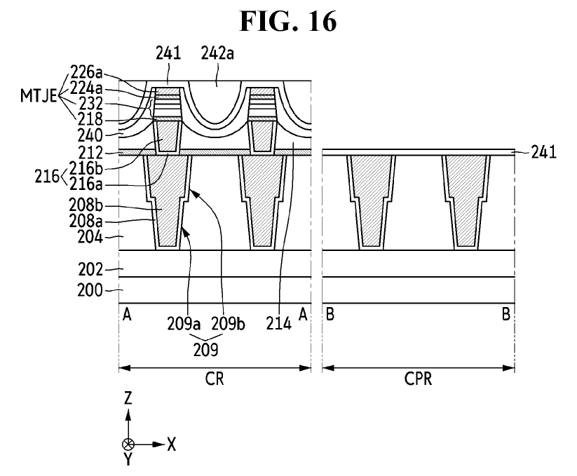

In FIG. 16, the second mold insulating layer 242a may be selectively formed on the second capping film 241 on the cell region CR. The second mold insulating layer 242a may fill a space between the memory structures MTJE on the second capping film 241. The second mold insulating layer 242a may not be formed on the second capping film 241 on the core peripheral region CPR.

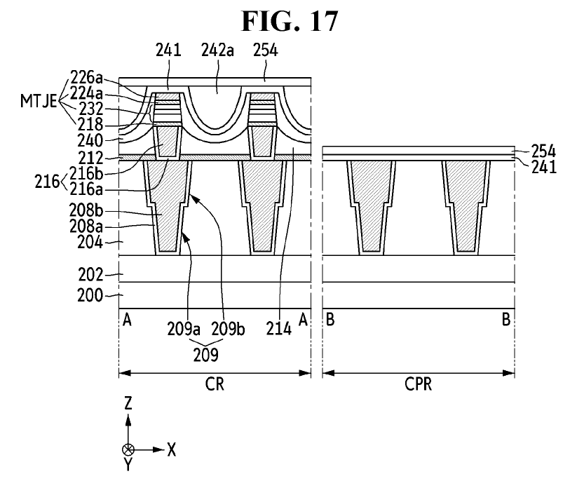

In FIG. 17, the etching stop film 254 may be formed on the second mold insulating layer 242a and the second capping film 241 on the cell region CR. The etching stop film 254 may be formed on the second capping film 241 on the core peripheral region CPR. That is, the etching stop film 254 on the cell region CR and the core peripheral region CPR may be integrally formed in the same process.

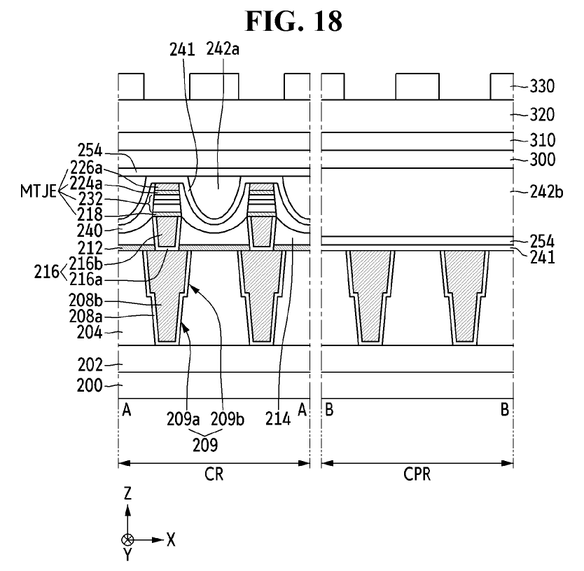

In FIG. 18, the third mold insulating layer 242b may be formed on the etching stop film 254 on the core peripheral region CPR. In this case, the third mold insulating layer 242b may include a material different from that of the second mold insulating layer 242a, and the third and second mold insulating layers 242a and 242b may be distinguished from each other. The upper surface of the third mold insulating layer 242b may be parallel with the upper surface of the etching stop film 254 of the cell region CR.

Afterwards, an anti-reflection film 300, a mask film 310, a pattern layer 320, and a photoresist 330 may be formed on the etching stop film 254 of the cell region CR and the third mold insulating layer 242b of the core peripheral region CPR. In this case, the anti-reflection film 300, the mask film 310, the pattern layer 320, and the photoresist 330 may be sequentially stacked. The anti-reflection film 300 may include silicon oxynitride (SiON). The anti-reflection film 300 may be formed through a CVD process or the like.

The pattern layer 320 may be formed on the mask film 310. For example, the pattern layer 320 may be formed of a carbon-spin-on hardmask material. The photoresist 330 may be formed on the pattern layer 320. An exposure process using the photoresist 330 may be performed for the electronic device 1.

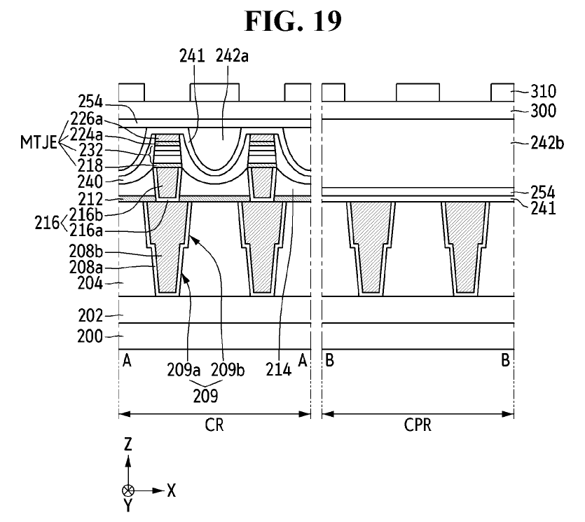

In FIG. 19, the mask film 310 may be patterned after the exposure process. That is, the mask film 310 may be etched.

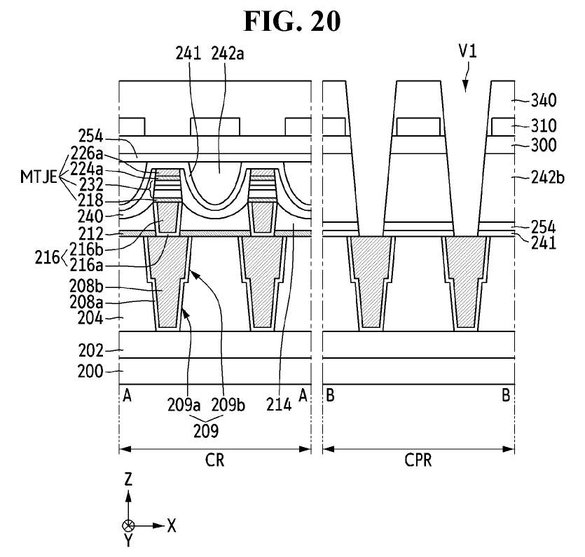

In FIG. 20, after the pattern layer 340 is formed on the mask film 310, the anti-reflection film 300 and the third mold insulating layer 242b may be etched. As a result, a first via hole V1 may be formed in the pattern layer 340, the anti-reflection film 300, and the third mold insulating layer 242b.

The etching stop film 254 and the second capping film 241 may be exposed by the first via hole V1. The first via hole V1 may be formed in the core peripheral region CPR, and may not be formed in the cell region CR. Accordingly, the third mold insulating layer 242b may be etched.

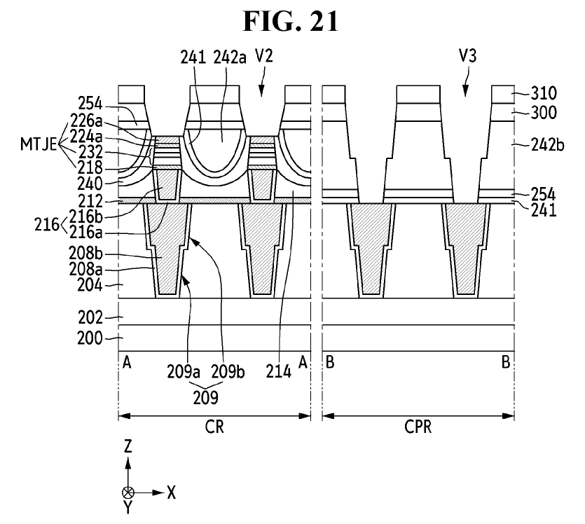

In FIG. 21, a second via hole V2 and a third via hole V3 may be formed as etching is performed using the mask film 310. The second via hole V2 may be formed in the cell region CR, and the third via hole V3 may be formed in the core peripheral region CPR. The second via hole V2 may be formed in the anti-reflection film 300, the etching stop film 254, and the second mold insulating layer 242a of the cell region CR.

The second via hole V2 may expose the memory structure MTJE, the upper surface of the first capping film 240, and a portion of a sidewall of the second capping film 241. The third via hole V3 may be formed in the anti-reflection film 300, the third mold insulating layer 242b, the etching stop film 254, and the second capping film 241 of the core peripheral region CPR. The third via hole V3 may expose the upper surface of the lower wiring 209 of the core peripheral region CPR. The third via hole V3 may include via holes having different widths.

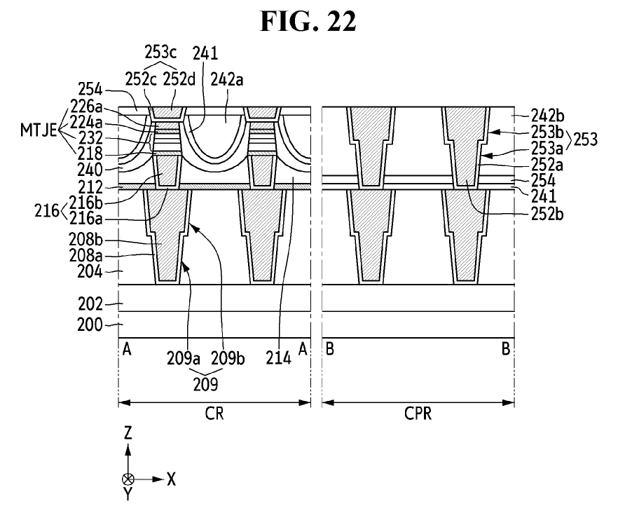

In FIG. 22, the anti-reflection film 300 and the mask film 310 may be removed, and the second via hole V2 and the third via hole V3 may be filled. The third metal structure 253c may be formed in the second via hole V2, and the first metal wiring structure 253 may be formed in the third via hole V3. As a result, the third metal structure 253c may be in contact with the memory structure MTJE, the upper surface of the first capping film 240, and the sidewall of the second capping film 241, and the first metal wiring structure 253 may be in contact with the upper surface of the third lower wiring 209.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A magnetic memory device comprising:
a substrate including a first region and a second region;
an upper insulating layer on the substrate;
a first material layer on the upper insulating layer, wherein the first material layer is in contact with a first surface of the upper insulating layer on the first region;
a lower electrode contact in the first material layer;
a memory structure on the lower electrode contact, the memory structure comprising a lower electrode, a magnetic tunnel junction structure, and an upper electrode;
a first mold insulating layer on the first material layer and between the first material layer and the memory structure;
an etching stop film on the memory structure and the first mold insulating layer;
a second mold insulating layer on the upper insulating layer on the second region; and
a second material layer on the second region, wherein the second material layer is in contact with the first surface of the upper insulating layer and is between the upper insulating layer and the second mold insulating layer,
wherein the second material layer is different from the first material layer.

2. The magnetic memory device of claim 1, wherein the first material layer is entirely contained on the first region of the substrate.

3. The magnetic memory device of claim 1, wherein a sidewall of the memory structure is in contact with the first mold insulating layer.

4. The magnetic memory device of claim 1, wherein the etching stop film is in contact with the second material layer, and the etching stop film is on the second region between the second material layer and the second mold insulating layer.

5. The magnetic memory device of claim 1, comprising a first capping film along a sidewall of the memory structure, wherein the first capping film is on the first material layer.

6. The magnetic memory device of claim 5, wherein the second material layer is between the first capping film and the first mold insulating layer.

7. The magnetic memory device of claim 1, wherein a first distance from the first surface of the upper insulating layer on the first region to an upper surface of the etching stop film is the same as a second distance from the first surface of the upper insulating layer on the second region to an upper surface of the second mold insulating layer.

8. The magnetic memory device of claim 1, wherein the first material layer comprises an oxide.

9. The magnetic memory device of claim 1, wherein the first material layer comprises at least one of carbon (C), nitrogen (N), or silicon (Si).

10. The magnetic memory device of claim 1, wherein the first material layer comprises at least one of nitrogen (N), oxygen (O), or aluminum (Al).

11. The magnetic memory device of claim 1, wherein the second material layer comprises at least one of carbon (C), nitrogen (N), or silicon (Si).

12. The magnetic memory device of claim 1, wherein the second material layer comprises at least one of nitrogen (N), oxygen (O), or aluminum (Al).

13. A magnetic memory device comprising:
a substrate including a first region and a second region;
an upper insulating layer on the substrate;
a first mold insulating layer on the upper insulating layer on the first region;
a lower electrode contact in the first mold insulating layer;
a memory structure on the lower electrode contact, the memory structure comprising a lower electrode, a magnetic tunnel junction structure, and an upper electrode;
a second mold insulating layer between the first mold insulating layer and the memory structure;
a third mold insulating layer on the upper insulating layer on the second region;
a first etching stop film on the memory structure and the second mold insulating layer in the first region;
a second etching stop film between the third mold insulating layer and the upper insulating layer in the second region;
a metal structure in contact with an upper surface of the memory structure in the first etching stop film;
a via contact in the second etching stop film; and
a first metal wiring on the via contact in the third mold insulating layer,
wherein an upper surface of the third mold insulating layer is at the same height as an upper surface of the first etching stop film.

14. The magnetic memory device of claim 13, wherein the first etching stop film is in contact with the second mold insulating layer.

15. The magnetic memory device of claim 13, comprising:
a first capping film along a sidewall of the memory structure and on the first mold insulating layer; and
a second capping film between the first capping film and the second mold insulating layer on the first capping film,
wherein the first etching stop film and the second etching stop film are in contact with the second capping film.

16. The magnetic memory device of claim 15, wherein the via contact extends into the second capping film on the second region.

17. The magnetic memory device of claim 13, wherein the second etching stop film contacts an upper surface of the upper insulating layer on the second region.

18. The magnetic memory device of claim 13, comprising a second metal wiring connected to the lower electrode contact in the upper insulating layer on the first region.

19. A device comprising:
a logic region; and
an electronic device including a memory region connected to the logic region,
wherein the memory region is embedded in the electronic device, and the memory region includes a cell region and a core peripheral region,
wherein the cell region includes:
a first substrate;
a first upper insulating layer on the first substrate;
a first mold insulating layer on the first upper insulating layer;
a diffusion barrier film in contact with an upper surface of the first upper insulating layer and between the first mold insulating layer and the first upper insulating layer;
a lower electrode contact in the first mold insulating layer and the diffusion barrier film;
a memory structure on the lower electrode contact, the memory structure comprising a lower electrode, a magnetic tunnel junction structure, and an upper electrode;
a first capping film along an upper surface of the first mold insulating layer and a sidewall of the memory structure;
a second capping film on an upper surface of the first capping film;
a second mold insulating layer between the first mold insulating layer and the memory structure and on the first mold insulating layer;
a first etching stop film on the memory structure and the second mold insulating layer; and
a metal structure in contact with an upper surface of the memory structure in the first etching stop film,
wherein the core peripheral region includes:
a second substrate,
a second upper insulating layer on the second substrate,
a third mold insulating layer on the second upper insulating layer,
a second etching stop film between the third mold insulating layer and the second upper insulating layer,
a via contact that extends into the second etching stop film, and
a metal wiring on the via contact in the third mold insulating layer, and
wherein an upper surface of the third mold insulating layer is at the same height as an upper surface of the first etching stop film.

20. The device of claim 19,
wherein the diffusion barrier film is spaced apart from an upper surface of the second upper insulating layer, and
wherein the second capping film is in contact with the upper surface of the second upper insulating layer.
